(19) United States
(12) Patent Application Publication
(10) Pub. No.: US 2026/0157197 A1
(43) Pub. Date: Jun. 4, 2026

(54) SEMICONDUCTOR PACKAGE

(71) Applicant: Samsung Electronics Co., Ltd., Suwon-si (KR)

(72) Inventor: Junghoon KANG, Suwon-si (KR)

(73) Assignee: Samsung Electronics Co., Ltd., Suwon-si (KR)

(21) Appl. No.: 19/405,726

(22) Filed: Dec. 2, 2025

(30) Foreign Application Priority Data
Dec. 2, 2024 (KR) 10-2024-0176899

(51) Int. Cl. H10W 70/60; G02B 6/12; H10F 55/00; H10W 70/63; H10W 90/15

(52) U.S. Cl. CPC H10W 70/618; G02B 6/12004; H10F 55/18; H10W 70/635; H10W 90/15; G02B 2006/12121; G02B 2006/12123

(57) ABSTRACT

A semiconductor package includes an interposer including a first optical bridge chip between the first redistribution structure and the second redistribution structure, and a first bridge chip between the first redistribution structure and the second redistribution structure and laterally separated from the first optical bridge chip, a plurality of semiconductor devices including a first semiconductor device and a second semiconductor device, the first and second semiconductor devices being on the interposer, and a first optical integrated circuit chip on the interposer and laterally separated from the first semiconductor device. A first region of the first optical bridge chip vertically overlaps a first region of the first semiconductor device. A first part of a second region of the first optical bridge chip vertically overlaps a first region of the second semiconductor device.

### CROSS-REFERENCE TO RELATED APPLICATION

This U.S. non-provisional application claims priority under 35 U.S.C. § 119 to Korean Patent Application No. 10-2024-0176899, filed on Dec. 2, 2024, in the Korean Intellectual Property Office, the disclosure of which is incorporated herein by reference in its entirety.

### BACKGROUND

Example embodiments relate to a semiconductor package.

Semiconductor packages may improve the functionality of electronic devices and integrate components. Semiconductor packages may include a package substrate on which various integrated circuits, such as memory chips or logic chips, are mounted. Semiconductor packages including optical integrated circuits are being researched for use in data centers and communication infrastructures, and other areas that are experiencing increased data traffic.

### SUMMARY

Example embodiments are directed to improving performance and productivity of a semiconductor package.

According to some example embodiments of the inventive concepts, a semiconductor package includes an interposer including a first redistribution structure, a second redistribution structure, a first optical bridge chip between the first redistribution structure and the second redistribution structure, and a first bridge chip between the first redistribution structure and the second redistribution structure and laterally separated from the first optical bridge chip, a plurality of semiconductor devices including a first semiconductor device and a second semiconductor device, the first semiconductor device being on the interposer, and the second semiconductor device being on the interposer and laterally separated from the first semiconductor device, and a first optical integrated circuit chip on the interposer and laterally separated from the first semiconductor device. a first region of the first optical bridge chip vertically overlaps a first region of the first semiconductor device, and a first part of a second region of the first optical bridge chip vertically overlaps a first region of the second semiconductor device.

According to some example embodiments of the inventive concepts, a semiconductor package includes an interposer including a first redistribution structure, a second redistribution structure, a first optical bridge chip between the first redistribution structure and the second redistribution structure, and a first bridge chip and a third bridge chip, the first bridge chip and the third bridge chip being between the first redistribution structure and the second redistribution structure and laterally separated from the first optical bridge chip, a plurality of semiconductor devices including a first semiconductor device and a second semiconductor device, the first and second semiconductor devices being on the interposer, a first optical integrated circuit chip on the interposer and laterally separated from the first semiconductor device, a first electronic integrated circuit chip electrically connected to the first optical integrated circuit chip, a first fiber array unit on the first optical integrated circuit chip, and a first memory device on the interposer and laterally separated from the first semiconductor device. The interposer includes a conductive post provided between the first redistribution structure and the second redistribution structure and is provided in at least one of a region between the first bridge chip and the first optical bridge chip and a region between the first bridge chip and an outer edge of the interposer, the first fiber array unit includes a plurality of optical fibers connected to the first optical integrated circuit chip, the first optical bridge chip and the first optical integrated circuit chip respectively include a first bridge optical waveguide and a first optical waveguide, and the first semiconductor device includes a logic chip, and the first memory device includes a plurality of stacked memory chips.

According to some example embodiments of the inventive concepts, a semiconductor package includes an interposer including a first redistribution structure, a second redistribution structure, a first optical bridge chip between the first redistribution structure and the second redistribution structure, a first bridge chip between the first redistribution structure and the second redistribution structure and laterally separated from the first optical bridge chip, and a plurality of conductive posts, a plurality of semiconductor devices including a first semiconductor device and a second semiconductor device, the first semiconductor device being on the interposer, and the second semiconductor device being on the interposer and laterally separated from the first semiconductor device, a first optical integrated circuit chip on the interposer and laterally separated from the first semiconductor device, a first electronic integrated circuit chip electrically connected to the first optical integrated circuit chip, and a first fiber array unit on the first optical integrated circuit chip. A first region of the first optical bridge chip vertically overlaps a first region of the first semiconductor device, and a first part of a second region of the first optical bridge chip vertically overlaps a first region of the second semiconductor device. A first region of the first bridge chip vertically overlaps a second region of the first semiconductor device, and a first part of a second region of the first bridge chip vertically overlaps a first region of the first optical integrated circuit chip. The first optical integrated circuit chip does not vertically overlap the first optical bridge chip. The at least one conductive post of the plurality of conductive posts is in at least one of a region between the first bridge chip and the first optical bridge chip and a region between the first bridge chip and an outer edge of the interposer. The first optical bridge chip includes a through-electrode passing through at least part of the first optical bridge chip and electrically connected to the first redistribution structure. The first optical bridge chip and the first optical integrated circuit chip respectively include a first bridge optical waveguide and a first optical waveguide. The first fiber array unit includes a plurality of optical fibers connected to the first optical integrated circuit chip. The first optical bridge chip includes a plurality of laser diodes and a plurality of photodiodes. A number of the laser diodes is equal to or greater than a number of the plurality of semiconductor devices. A number of the photodiodes is equal to or greater than the number of the plurality of semiconductor devices. The first optical bridge chip includes a plurality of interfaces electrically connected to the plurality of semiconductor devices, and a plurality of optical channels for communication between the plurality of interfaces. The first optical bridge chip is configured to directly communicate with the plurality of interfaces in a single hop.

According to some example embodiments, a method of manufacturing a semiconductor package includes positioning a first redistribution structure on a carrier, forming a plurality of conductive posts on the first redistribution structure, arranging a first optical bridge chip, a first bridge chip, and a second bridge chip on the first redistribution structure, the first optical bridge chip including a plurality of first upper chip pads on an upper surface thereof, and the first bridge chip and the second bridge chip each including a plurality of second upper chip pads, forming a first encapsulant on the first redistribution structure and covering the plurality of conductive posts, the first optical bridge chip, and the first bridge chip, removing the first encapsulant to expose the plurality of first upper chip pads and the plurality of second upper chip pads, forming a second redistribution structure on the first encapsulant, arranging a first semiconductor device, a second semiconductor device, a first optical integrated circuit chip, and a second optical integrated circuit chip, on the second redistribution structure, arranging a first electronic integrated circuit chip and a first fiber array unit on the first optical integrated circuit chip, arranging a second electronic integrated circuit chip and a second fiber array unit on the second optical integrated circuit chip, removing the carrier from the first redistribution structure, and forming a plurality of lower connection terminals may be respectively formed on a plurality of lower connection pads on a lower surface of the first redistribution structure.

According to some example embodiments, a first region of the first optical bridge chip vertically overlaps a first region of the first semiconductor device, and a first part of a second region of the first optical bridge chip vertically overlaps a first region of the second semiconductor device. According to some example embodiments, the first optical integrated circuit chip does not vertically overlap the first optical bridge chip, and one of side surfaces of the first optical integrated circuit chip faces one of side surfaces of each of the first semiconductor device and the second semiconductor device. According to some example embodiments, at least one conductive post of the plurality of conductive posts is in at least one of a region between the first bridge chip and the first optical bridge chip and a region on an outer edge of the first bridge chip. According to some example embodiments, the first optical bridge chip includes a through-electrode passing through at least part of the first optical bridge chip, and the through-electrode is electrically connected to the first redistribution structure.

### BRIEF DESCRIPTION OF THE DRAWINGS

Example embodiments of the inventive concepts will be more clearly understood from the following detailed description taken in conjunction with the accompanying drawings in which:

FIG. 1 is a plan view of a semiconductor package according to some example embodiments.

FIG. 2A is a cross-sectional view taken along line A-A′ of the semiconductor package of FIG. 1.

FIG. 2B is an enlarged cross-sectional view of a portion of the semiconductor package of FIG. 2A.

FIG. 3 is a cross-sectional view taken along line B-B′ of the semiconductor package of FIG. 1.

FIG. 4 is a cross-sectional view of a semiconductor package according to some example embodiments.

FIG. 5 is a plan view of a semiconductor package according to some example embodiments.

FIG. 6 is a cross-sectional view of a semiconductor package according to some example embodiments.

FIG. 7 is a cross-sectional view of a semiconductor package according to some example embodiments.

FIG. 8 is a cross-sectional view of semiconductor package according to some example embodiments.

FIGS. 9A, 9B, 9C, 9D, 9E, and 9F are cross-sectional views illustrating operations in a method of manufacturing a semiconductor package according to some example embodiments.

### DETAILED DESCRIPTION OF THE EMBODIMENTS

Hereinafter, example embodiments of the inventive concepts are described in detail with reference to the attached drawings.

Example embodiments are provided to more completely describe the inventive concepts to those skilled in the art, and the following example embodiments may be modified into various other forms, and the inventive concepts are not limited to the following example embodiments. The example embodiments are provided to make the inventive concepts more faithful and complete and for the understanding of those skilled in the art. In the drawings, the thickness of layers, films, panels, regions, etc., are exaggerated for clarity.

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

In some example embodiments, the first direction refers to the X direction, the second direction refers to the Y direction, and the first direction may be perpendicular to the second direction. The third direction is the Z direction, and the third direction may be perpendicular to the first direction and the second direction. A horizontal plane or a plane refers to an X-Y plane. An upper surface of a certain object refers to a surface in a positive third direction with respect to the certain object, and a lower surface of a certain object refers to a surface in a negative third direction with respect to the certain object.

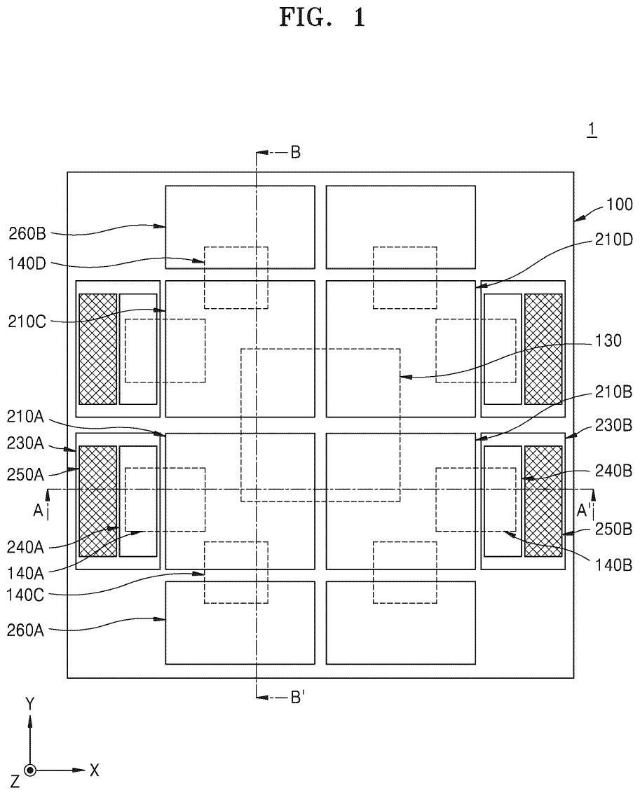

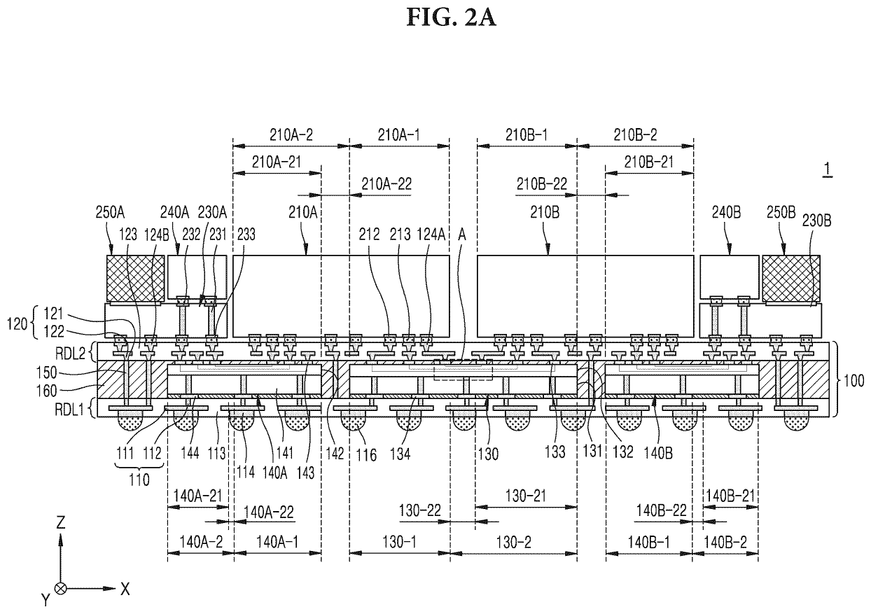

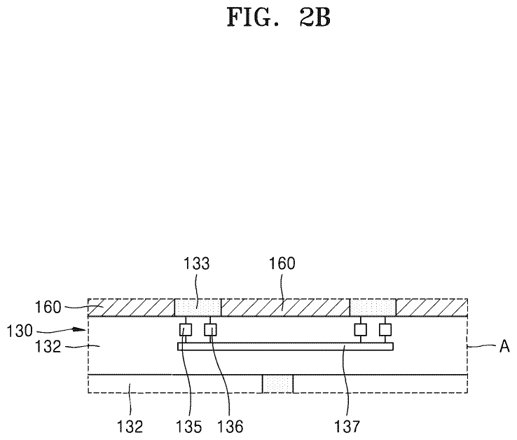

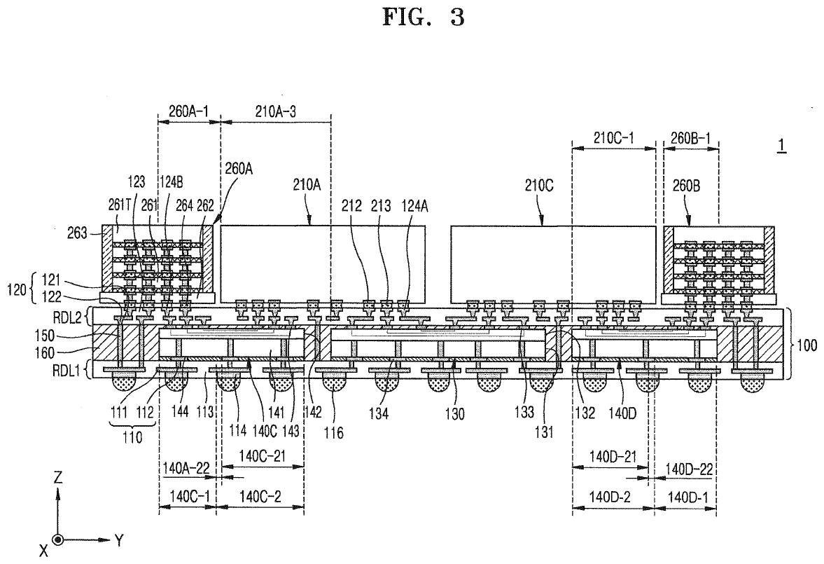

FIG. 1 is a plan view of a semiconductor package 1 according to some example embodiments. FIG. 2A is a cross-sectional view taken along line A-A′ of the semiconductor package 1 of FIG. 1. FIG. 2B is an enlarged cross-sectional view of a portion A of the semiconductor package of FIG. 2A. FIG. 3 is a cross-sectional view taken along line B-B′ of the semiconductor package 1 of FIG. 1.

Referring to FIG. 1, FIG. 2A, FIG. 2B, and FIG. 3, the semiconductor package 1 may include an interposer 100 and include a first semiconductor device 210A, a second semiconductor device 210B, a third semiconductor device 210C, a fourth semiconductor device 210D, a first optical integrated circuit chip 230A, a second optical integrated circuit chip 230B, a first electronic integrated circuit chip 240A, a first fiber array unit 250A, a second electronic integrated circuit chip 240B, and a second fiber array unit 250B, which are positioned or arranged on the interposer 100.

The interposer 100 may include a first redistribution structure RDL1 and a second redistribution structure RDL2, and include a first bridge chip 140A, a second bridge chip 140B, a third bridge chip 140C, a fourth bridge chip 140D, a first optical bridge chip 130, a plurality of conductive posts 150, and a first encapsulant 160, which are positioned or arranged between the first redistribution structure RDL1 and the second redistribution structure RDL2.

The first redistribution structure RDL1 may include at least one first redistribution insulating layer 113 and at least one first redistribution pattern 110. The first redistribution pattern 110 may include a plurality of first redistribution line patterns 111 and a plurality of first redistribution via patterns 112. The first redistribution structure RDL1 may be referred to as a lower redistribution structure. The first redistribution insulating layer 113 may surround the first redistribution pattern 110. In some example embodiments, the first redistribution structure RDL1 may include a plurality of stacked first redistribution insulating layers 113. In some example embodiments, two or more redistribution insulating layers may be included in the first redistribution structure RDL1.

In some example embodiments, the first redistribution structure RDL1 may be formed through a redistribution process. Through the redistribution process, the first redistribution structure RDL1 may include the first redistribution insulating layer 113 and include the plurality of first redistribution line patterns 111 and the plurality of first redistribution via patterns 112 which are included in the first redistribution pattern 110 and alternately formed.

The first redistribution insulating layer 113 may be formed of a material composed of or including, for example, an organic compound. In some example embodiments, at least one first redistribution insulating layer 113 may be formed of or include an organic polymer material. In some example embodiments, the first redistribution insulating layer 113 may be formed of or include photosensitive polyimide (PSPI). The first redistribution insulating layer 113 may be formed of or include a photosensitive dielectric. The first redistribution insulating layer 113 may be or include, for example, a photosensitive polymer. The photosensitive polymer may be or include at least one of, for example, photosensitive polyimide, polybenzoxazole, phenol-based polymer, and/or benzocyclobutene-based polymer.

The first redistribution pattern 110 may include the plurality of first redistribution line patterns 111 and the plurality of first redistribution via patterns 112. The first redistribution pattern 110 may include one of metals, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy of the metals, but example embodiments are not limited thereto.

A plurality of lower connection pads 114 may be provided on a lower surface of the first redistribution structure RDL1. A plurality of lower connection terminals 116 respectively corresponding to the plurality of lower connection pads 114 may be provided.

The first optical bridge chip 130, the first bridge chip 140A, and the second bridge chip 140B may be provided on an upper surface of the first redistribution structure RDL1. The first optical bridge chip 130, the first bridge chip 140A, and the second bridge chip 140B may be laterally (e.g., horizontally in the X-direction) separated from each other on the upper surface of the first redistribution structure RDL1. The second bridge chip 140B may be same as or similar in some respects to the first bridge chip 140A and may be best understood with reference thereto.

The first optical bridge chip 130 may include a first optical bridge substrate 131, a first optical wiring layer 132 formed on one (or upper) surface of the first optical bridge substrate 131, a first optical bridge through-electrode passing through at least part of the first optical bridge substrate 131, a first lower chip pad 134 electrically connected to the first optical bridge through-electrode and provided on a lower surface of the first optical bridge substrate 131, and a plurality of first upper chip pads 133 electrically connected to the first optical wiring layer 132 and provided on an upper surface of the first optical bridge chip 130. The first optical bridge chip 130 may be arranged such that the first optical wiring layer 132 faces the second redistribution structure RDL2.

The first optical bridge chip 130 may further include a plurality of individual devices of different types. For example, the plurality of individual devices may include various micro electronic devices, such as a complementary metal-oxide semiconductor (CMOS) transistor, a metal-oxide-semiconductor field effect transistor (MOSFET), a system large scale integration (LSI), an image sensor such as a CMOS imaging sensor (CIS), a micro-electro-mechanical system (MEMS), an active device, and/or a passive device.

The first optical bridge chip 130 may include a photonic integrated circuit (PIC). The first optical bridge chip 130 may include an electronic integrated circuit (EIC). The photonic integrated circuit may input and output an optical signal. The first optical bridge chip 130 may receive an electrical signal, convert the electrical signal into an optical signal, and internally transmit data through the optical signal, and when outputting a signal, first optical bridge chip 130 may convert the optical signal back into an electrical signal and transmit the electrical signal.

The first optical wiring layer 132 may include at least one optical waveguide. The optical waveguide of the first optical bridge chip 130 may be referred to as a first bridge optical waveguide. The optical waveguide may transmit signals between chips using light. For example, the optical waveguide may be connected to an electro-optical converter, an opto-electronic converter, and so on to form an optical circuit. The first optical bridge chip 130 may be electrically connected to the first semiconductor device 210A and the second semiconductor device 210B through the plurality of first upper chip pads 133. The optical waveguide included in the first optical wiring layer 132 may be a medium for signal transmission between the first semiconductor device 210A and the second semiconductor device 210B.

For example, the first optical wiring layer 132 may be formed by forming a lower cladding layer formed of silicon oxide, silicon nitride, or so on, depositing and patterning a core portion by using a material having a higher refractive index than the lower cladding layer, and then forming an upper cladding layer in this order.

The first optical bridge chip 130 may include an electro-optic converter and an opto-electronic converter. The electro-optic converter may convert a received electrical signal into an optical signal and transmit the optical signal through the optical waveguide described above. The optical signal transmitted through the optical waveguide may be converted back into an electrical signal by the opto-electronic converter. The opto-electronic converter may include a photodetector, and the electro-optic converter may include a laser diode or an optical modulator.

For example, a laser diode (LD) may convert an electrical signal, which is received by the first optical bridge chip 130 from the first semiconductor device 210A, into an optical signal. The optical signal may be transmitted through the optical waveguide, and a photodiode (PD) may receive the optical signal and convert the optical signal into an electrical signal. A single hop (1-hop) communication capable of direct communication between all interfaces may be implemented by the first optical bridge chip 130, as discussed below.

Referring to FIG. 2B, the first optical bridge chip 130 may be embedded in the first encapsulant 160. The first optical wiring layer 132 may be on one side (for example, an upper side) of the first optical bridge chip 130. The first optical wiring layer 132 may include at least one first bridge optical waveguide 137 extending in a horizontal direction, and the first bridge optical waveguide 137 may serve as a path for transmitting optical signals between a plurality of laser diodes 135 and a plurality of corresponding photodiodes 136.

A plurality of first upper chip pads 133 may be electrically connected to the plurality of laser diodes 135 and the plurality of photodiodes 136, respectively. The plurality of laser diodes 135 and the plurality of photodiodes 136 may be provided on the first optical bridge substrate 131 and optically coupled to the first optical wiring layer 132. The first bridge optical waveguide 137 may be provided in correspondence with one laser diode 135 and one photodiode 136.

The plurality of laser diodes 135 and the plurality of photodiodes 136 may be optically coupled to the first bridge optical waveguide 137. An electrical signal received through the plurality of first upper chip pads 133 may be converted into an optical signal by the laser diode 135, may be transmitted to the corresponding photodiode 136 through the first bridge optical waveguide 137, and may be converted back into an electrical signal by the photodiode 136, thereby performing signal transmission.

A first region 130-1 of the first optical bridge chip 130 may overlap a first region 210A-1 of the first semiconductor device 210A in a vertical direction. The first region 130-1 of the first optical bridge chip 130 may partially overlap the first region 210A-1 of the first semiconductor device 210A in a planar view. For example, in order to reduce a signal transmission distance of an electric signal transmission, the first optical bridge chip 130 may transmit and receive electric signals to and from the first semiconductor device 210A through the second redistribution structure RDL2 in the first region 130-1 where the first optical bridge chip 130 overlaps the first semiconductor device 210A and regions of the first optical bridge chip 130 adjacent to the first region 130-1.

The first optical bridge chip 130 includes a second region 130-2 adjacent the first region 130-1 of the first optical bridge chip 130. A first part 130-21 of the second region 130-2 may partially overlap a first region 210B-1 of the second semiconductor device 210B in a vertical direction. The first optical bridge chip 130 may thus vertically overlap the first semiconductor device 210A and the second semiconductor device 210B via the first region 130-1 and the first part 130-21 of the second region 130-2. The second region 130-2 of the first optical bridge chip 130 may include a second part 130-22 that is between the first region 130-1 and the first part 130-21 and that does not vertically overlap the first semiconductor device 210A and the second semiconductor device 210B.

The first bridge chip 140A may include a first bridge substrate 141, a first wiring layer 142 formed on one (or upper) surface of the first bridge substrate 141, a first bridge through-electrode passing through at least part of the first bridge substrate 141, a first lower chip pad 144 electrically connected to the first bridge through-electrode and provided on a lower surface of the first bridge substrate 141, and a plurality of first upper chip pads 143 electrically connected to the first wiring layer 142 and provided on an upper surface of the first bridge chip 140A. The first bridge chip 140A may be arranged such that the first wiring layer 142 faces the second redistribution structure RDL2.

The first semiconductor device 210A may include a second region 210A-2 adjacent the first region 210A-1. The second region 210A-2 may include a first part 210A-21, and a second part 210A-22 that is between the first region 210A-1 and the first part 210A-21. A first region 140A-1 of the first bridge chip 140A may overlap the first part 210A-21 of the second region 210A-2 of the first semiconductor device 210A in a vertical direction. The first region 140A-1 of the first bridge chip 140A may overlap the first part 210A-21 in a planar view. The first bridge chip 140A may include a second region 140A-2 adjacent the first region 140A-1. The second region 140A-2 may include a first part 140A-21, and a second part 140A-22 that is between the first region 140A-1 and the first part 140A-21. The first part 140A-21 of the second region 140A-2 of the first bridge chip 140A may overlap the first optical integrated circuit chip 230A in the vertical direction. The first bridge chip 140A may thus vertically overlap the first semiconductor device 210A and the first optical integrated circuit chip 230A via the first region 140A-1 and the first part 140A-21 of the second region 140A-2. The second part 140A-22 of the second region 140A-2 may not vertically overlap the first semiconductor device 210A and the first optical integrated circuit chip 230A. A signal transmitted through the first bridge chip 140A may include a signal transmitted between the first semiconductor device 210A and the first optical integrated circuit chip 230A.

The second semiconductor device 210B may include a second region 210B-2 adjacent the first region 210B-1. The second region 210B-2 may include a first part 210B-21, and second part 210B-22 that is between the first region 210B-1 and the first part 210B-21. A first region 140B-1 of the second bridge chip 140B may vertically overlap the first part 210B-21 of the second region 210B-2 of the second semiconductor device 210B. The first region 140B-1 of the second bridge chip 140B may overlap the first part 210B-21 of the second region 210B-2 of the second semiconductor device 210B in a planar view. The second bridge chip 140B may include a second region 140B-2 adjacent the first region 140B-1. The second region 140B-2 may include a first part 140B-21, and a second part 140B-22 that is between the first region 140B-1 and first part 140B-21. The first part 140B-21 of the second region 140B-2 of the second bridge chip 140B may overlap the second optical integrated circuit chip 230B in the vertical direction. The second bridge chip 140B may thus vertically overlap the second semiconductor device 210B and the second optical integrated circuit chip 230B via the first region 140B-1 and the first part 140B-21 of the second region 140B-2. The second part 140B-22 of the second region 140B-2 may not vertically overlap the second semiconductor device 210B and the second optical integrated circuit chip 230B.

The second redistribution structure RDL2 may be vertically (e.g., in the Z-direction) separated from the first redistribution structure RDL1, and the first optical bridge chip 130, the first bridge chip 140A, and the second bridge chip 140B may be provided between the second redistribution structure RDL2 and the first redistribution structure RDL1.

The second redistribution structure RDL2 may include at least one second redistribution insulating layer 123 and at least one second redistribution pattern 120. The second redistribution pattern 120 may include a plurality of second redistribution line patterns 121 and a plurality of second redistribution via patterns 122. The second redistribution structure RDL2 may be referred to as an upper redistribution structure. The second redistribution insulating layer 123 may surround the second redistribution pattern 120. In some example embodiments, the second redistribution structure RDL2 may include a plurality of stacked second redistribution insulating layers 123. In some example embodiments, two or more redistribution insulating layers may be included in the second redistribution structure RDL2.

A side surface of the second redistribution structure RDL2 and a side surface of the first redistribution structure RDL1 may be aligned in the vertical direction. A side surface of a first encapsulant 160 described below may also be aligned in the vertical direction with the side surface of the second redistribution structure RDL2 and the side surface of the first redistribution structure RDL1.

The plurality of conductive posts 150 may be provided between the first redistribution structure RDL1 and the second redistribution structure RDL2. The plurality of conductive posts 150 may be provided in at least one among a region between the first bridge chip 140A and an outer edge (e.g., horizontally outer edge) of the interposer 100, a region between the first bridge chip 140A and the first optical bridge chip 130, a region between the second bridge chip 140B and the first optical bridge chip 130, a region between the second bridge chip 140B and the outer edge (e.g., horizontally outer edge) of the interposer 100, a periphery of the first bridge chip 140A, a periphery of the second bridge chip 140B, and a periphery of the first optical bridge chip 130.

The first semiconductor device 210A may be provided or arranged over the interposer 100. For example, the first semiconductor device 210A may be provided or arranged over the second redistribution structure RDL2. The first semiconductor device 210A may include, for example, at least one semiconductor chip. The first semiconductor device 210A may include a plurality of first device connection pads 212 on one surface thereof, and the plurality of first device connection pads 212 may correspond to a plurality of second upper surface connection pads 124A provided on the second redistribution structure RDL2. The plurality of first device connection pads 212 of the first semiconductor device 210A may correspond to the plurality of second upper surface connection pads 124A of the second redistribution structure RDL2, and a plurality of device connection terminals (213) may be provided therebetween.

In some example embodiments, the semiconductor chip included in the first semiconductor device 210A may include a logic chip. For example, the semiconductor chip of a second semiconductor device 210B may be a system on chip (SoC) or a logic chip. The logic chip may be a microprocessor. For example, the logic chip may be an application processor (AP), a microprocessor, a central processing unit (CPU), a graphics processing unit (GPU), a neural processing unit (NPU), a controller, or an application specific integrated circuit (ASIC).

The second semiconductor device 210B may be provided on the interposer 100, be adjacent to the first semiconductor device 210A, and be laterally (e.g., horizontally) separated from the first semiconductor device 210A. The second semiconductor device 210B may be same as or similar in some respects to the first semiconductor device 210A and may be best understood with reference thereto.

The first optical integrated circuit chip 230A may be provided or arranged on the interposer 100 and may be laterally separated from the first semiconductor device 210A. For example, the first optical integrated circuit chip 230A may be provided or arranged between the first semiconductor device 210A and an outer edge of the interposer 100. One or more side surfaces of the first optical integrated circuit chip 230A may face one or more side surfaces of the first semiconductor device 210A. The first optical integrated circuit chip 230A may include at least one through-hole electrode 231. The through-hole electrode 231 may electrically connect a lower chip pad 233 provided on a lower surface of the first optical integrated circuit chip 230A to an upper chip pad 232 provided on a top surface of the first optical integrated circuit chip 230A. A second upper surface connection pad 124B provided on the second redistribution structure RDL2 may be electrically connected to the first optical integrated circuit chip 230A.

The first electronic integrated circuit chip 240A may be provided on the first optical integrated circuit chip 230A. The first electronic integrated circuit chip 240A may be electrically connected to the upper chip pad 232 of the first optical integrated circuit chip 230A, and the first electronic integrated circuit chip 240A may exchange electrical signals with the first optical integrated circuit chip 230A.

The first optical integrated circuit chip 230A may include an electro-optic converter, an opto-electronic converter, and an optical waveguide. The optical waveguide of the first optical integrated circuit chip 230A may be referred to as a first optical waveguide. The electro-optic converter may convert a received electrical signal into an optical signal, and transmit the optical signal through the optical waveguide. The opto-electronic converter may convert an optical signal transmitted through the optical waveguide back into an electrical signal. The opto-electronic converter may include a photodetector, and the electro-optic converter may include a laser diode or an optical modulator.

The first electronic integrated circuit chip 240A may include CMOS drivers, transimpedance amplifiers, and so on to perform a function, such as controlling high-frequency signaling of an optical integrated circuit. For example, the first electronic integrated circuit chip 240A may perform digital signal processing, amplification, filtering, and the like on an electrical signal converted by the opto-electronic converter of the first optical integrated circuit chip 230A. The electrical signal processed by the first electronic integrated circuit chip 240A may be transmitted to other components through the interposer 100. Similarly, after electrical signals transmitted through the interposer 100 from other components are appropriately processed by the first electronic integrated circuit chip 240A, the electrical signals may be converted into optical signals by the electro-optic converter of the first optical integrated circuit chip 230A.

The first optical integrated circuit chip 230A may receive an optical signal from an external device. For example, the first optical integrated circuit chip 230A may have an intermediate optical coupling structure (OCS) connected to an optical fiber for transmitting an optical signal to the first optical integrated circuit chip 230A. For example, the first optical integrated circuit chip 230A may be connected to the optical fiber, which transmits the optical signal, through the intermediate OCS, such as an edge coupling or a grating coupler. For example, the first optical integrated circuit chip 230A may be connected to the optical fiber, which transmits an optical signal, through the first fiber array unit 250A.

In some example embodiments, the first fiber array unit 250A may be provided or arranged on the first optical integrated circuit chip 230A. The first fiber array unit 250A may be laterally separated from the first electronic integrated circuit chip 240A and may be farther from the first semiconductor device 210A than the first electronic integrated circuit chip 240A. In some example embodiments, the first fiber array unit 250A may be closer to an outer edge of the interposer 100 than the first electronic integrated circuit chip 240A. In other words, the first electronic integrated circuit chip 240A may be between the first fiber array unit 250A and the first semiconductor device 210A.

The first fiber array unit 250A may include a plurality of optical fibers. The plurality of optical fibers of the first fiber array unit 250A may be arranged in an aligned state with a desired (or, alternatively preset) interval. The plurality of optical fibers may be connected to an external optical fiber that transmits an optical signal from the outside. For example, multi-channel optical signals may be transmitted and received through the plurality of optical fibers. A signal received through the first fiber array unit 250A may be received by the first optical integrated circuit chip 230A, and opto-electronic conversion may be performed on the signal. In some example embodiments, an optical signal transmitted from the first optical integrated circuit chip 230A may be transmitted externally through the first fiber array unit 250A.

The second optical integrated circuit chip 230B may be provided or arranged on the interposer 100 and may be laterally separated from the second semiconductor device 210B. For example, the second optical integrated circuit chip 230B may be provided or arranged between the second semiconductor device 210B and an outer edge of the interposer 100. The first optical integrated circuit chip 230A may include a through-electrode. The second electronic integrated circuit chip 240B may be provided or arranged on the second optical integrated circuit chip 230B. The second electronic integrated circuit chip 240B may be electrically connected to the second optical integrated circuit chip 230B to exchange electrical signals therebetween.

The second optical integrated circuit chip 230B may receive an optical signal from the outside. For example, the second optical integrated circuit chip 230B may have an intermediate optical coupling structure connected to an optical fiber for transmitting an optical signal to the second optical integrated circuit chip 230B. For example, the second optical integrated circuit chip 230B may be connected to the optical fiber, which transmits an optical signal, through the second fiber array unit 250B.

In some example embodiments, the second fiber array unit 250B may be provided or arranged on the second optical integrated circuit chip 230B. The second fiber array unit 250B may be laterally separated from the second electronic integrated circuit chip 240B and may be farther from the second semiconductor device 210B than the second electronic integrated circuit chip 240B. In some example embodiments, the second fiber array unit 250B may be closer to an outer edge of the interposer 100 than the second electronic integrated circuit chip 240B. In other words, the second electronic integrated circuit chip 240B may be between the second fiber array unit 250B and the second semiconductor device 210B.

As illustrated in FIG. 1 and FIG. 3, a first memory device 260A may be provided (or arranged) on the interposer 100. The first memory device 260A may include a memory chip. A memory chip of the first memory device 260A may include various types of memory circuits, such as dynamic random access memory (DRAM), static random access memory (SRAM), flash memory, phase-change random access memory (PRAM), resistive random access memory (ReRAM), ferroelectric random access memory (FeRAM), and magnetic random access memory (MRAM).

For example, the first memory device 260A may include a plurality of stacked first memory chips 261. The first memory device 260A may be a high bandwidth memory (HBM), and the second semiconductor chip 262 may be referred to as an HBM controller die. The second semiconductor chip 262 may also be referred to as an interface die, a base die, a logic die, a master die, or so on. The first memory chip 261 may be a memory chip including multiple memory cells and may be referred to as a DRAM die.

At least one or more of the plurality of first memory chips 261 and the second semiconductor chip 262 may each include a plurality of through-electrodes. An uppermost first memory chip 261T, which is farthest from the second semiconductor chip 262 in the vertical direction, among the plurality of first memory chips 261 may not have a plurality of through-electrodes. The first memory device 260A may be electrically connected to the second redistribution structure RDL2 through a device connection terminal 264. At least some of the plurality of first memory chips 261 and the second semiconductor chip 262 may be surrounded by a second sealing material 263.

The second memory device 260B may be provided (or arranged) on the interposer 100. The second memory device 260B may be same as or similar in some respects to the first memory device 260A and may be best understood with reference thereto.

The third bridge chip 140C may be provided (or arranged) inside the interposer 100. The third bridge chip 140C may be laterally separated from the first optical bridge chip 130, the first bridge chip 140A, and the second bridge chip 140B.

A first region 140C-1 of the third bridge chip 140C may vertically overlap a region 260A-1 of the first memory device 260A. The first region 140C-1 of the third bridge chip 140C may overlap the region 260A-1 of the first memory device 260A in a planar view. The third bridge chip 140C may include a second region 140C-2 adjacent the first region 140C-1. The second region 140C-2 may include a first part 140C-21, and a second part 140C-22 that is between the first region 140C-1 and the first part 140C-21. The first part 140C-21 of the second region 140C-2 of the third bridge chip 140C may overlap a third region 210A-3 of the first semiconductor device 210A in the vertical direction. The third bridge chip 140C may thus vertically overlap the first semiconductor device 210A and the first memory device 260A via the first region 140C-1 and the first part 140C-21 of the second region 140C-2. The second part 140C-22 of the second region 140C-2 may not vertically overlap the first semiconductor device 210A and the first memory device 260A. A signal transmitted through the third bridge chip 140C may include another signal transmitted between the first memory device 260A and the first semiconductor device 210A.

The fourth bridge chip 140D may be provided (or arranged) inside the interposer 100. The fourth bridge chip 140D may be laterally separated from the first optical bridge chip 130, the first bridge chip 140A, the second bridge chip 140B, and the third bridge chip 140C. A region 140D-1 of the fourth bridge chip 140D may vertically overlap a region 260B-1 of the second memory device 260B. The fourth bridge chip 140D may include a second region 140D-2 adjacent the first region 140D-1. The second region may include a first part 140D-21, and a second part 140D-22 that is between the first region 140D-1 and the first part 140D-21. The first part 140D-21 may overlap a region 210C-1 of the third semiconductor device 210C in the vertical direction. The fourth bridge chip 140D may thus vertically overlap the second memory device 260B and the third semiconductor device 210C via the first region 140D-1 and the first part 140D-21 of the second region 140D-2. The second part 140D-22 of the second region 140D-2 may not vertically overlap the second memory device 260B and the third semiconductor device 210C. The fourth bridge chip 140D may be same as or similar in some respects to the first bridge chip 140A and may be best understood with reference thereto.

In the semiconductor package 1, signals may be transmitted through the interposer 100 among the first semiconductor device 210A, the second semiconductor device 210B, the first memory device 260A, the second memory device 260B, the first optical integrated circuit chip 230A, and the second optical integrated circuit chip 230B which are mounted on the interposer 100. In some example embodiments, signal transmission between the first semiconductor device 210A, the second semiconductor device 210B, the first memory device 260A, the second memory device 260B, the first optical integrated circuit chip 230A, and/or the second optical integrated circuit chip 230B may be performed through the first optical bridge chip 130, the first bridge chip 140A, the second bridge chip 140B, the third bridge chip 140C, the fourth bridge chip 140D, the first redistribution structure RDL1, the second redistribution structure RDL2, and/or the plurality of conductive posts 150.

For example, signal transmission between the first semiconductor device 210A and the second semiconductor device 210B may be performed through the first optical bridge chip 130, signal transmission between the first semiconductor device 210A and the first optical integrated circuit chip 230A may be performed through the first bridge chip 140A, signal transmission between the second semiconductor device 210B and the second optical integrated circuit chip 230B may be performed through the second bridge chip 140B, signal transmission between the first memory device 260A and the first semiconductor device 210A may be performed through the third bridge chip 140C, and signal transmission between the second memory device 260B and the first semiconductor device 210A may be performed through the fourth bridge chip 140D.

In some example embodiments, signal transmission between the first semiconductor device 210A and the second semiconductor device 210B may be performed through the first optical bridge chip 130. Signal transmission between the first semiconductor device 210A and the second semiconductor device 210B may require a relatively higher bandwidth. For example, a plurality of semiconductor devices including the first semiconductor device 210A and the second semiconductor device 210B may transmit signals through the first optical bridge chip 130. For example, as illustrated in FIG. 1, four semiconductor chips may be provided on the interposer 100. However, this is merely an example, and example embodiments of the inventive concepts are not limited to four semiconductor chips, and may be equally applicable to configurations including more than 4 or less than 4 semiconductor chips.

The plurality of semiconductor devices may transmit and receive signals through the first optical bridge chip 130. The plurality of semiconductor devices may each be electrically connected to the first optical bridge chip 130 through the second redistribution pattern 120 of the second redistribution structure RDL2. The plurality of semiconductor devices may be respectively connected to a plurality of interfaces of the first optical bridge chip 130.

The plurality of semiconductor devices connected to the plurality of interfaces may exchange signals with each other through a plurality of channels. For example, the first optical bridge chip 130 may include a plurality of optical waveguides, and the number of channels may be affected by an arrangement and configurations of the plurality of optical waveguides. A plurality of semiconductor devices including the first semiconductor device 210A and the second semiconductor device 210B may be connected to each other in a single hop through the first optical bridge chip 130. For example, an arrangement of the plurality of optical waveguides may include an optical waveguide arrangement of a crossbar switch structure or a matrix type.

For example, the first optical bridge chip 130 may include an interface including a plurality of first upper chip pads 133, and the interface may directly transmit signals to an interface connected to other semiconductor devices through the first optical bridge chip 130. A plurality of interfaces may be directly connected to each other. Therefore, the plurality of interfaces may be directly connected to each other in a single hop. For example, an interface of the first optical bridge chip 130 may include a laser diode and a photodiode.

Signal transmission between the first semiconductor device 210A and the second semiconductor device 210B may be performed through an electro-optic converter, an opto-electronic converter, and an optical waveguide included in the first optical bridge chip 130. For example, an electrical signal transmitted from the first semiconductor device 210A may be converted into an optical signal by the electro-optic converter, and the optical signal may be transmitted through the optical waveguide, and then converted back into the electrical signal by the opto-electronic converter, and the electrical signal may be transmitted to the second semiconductor device 210B. The electro-optic converter may include, for example, a laser diode, and an electrical signal may be converted into an optical signal by the laser diode. The opto-electronic converter may include, for example, a photodiode, and an optical signal may be converted into an electrical signal by the photodiode.

One or more photodiodes and one or more laser diodes for converting electrical signals transmitted to and received from the first semiconductor device 210A may be included in the first optical bridge chip 130, and similarly, one or more photodiodes and one or more laser diodes for converting electrical signals transmitted to and received from the second semiconductor device 210B may be included in the first optical bridge chip 130. In some example embodiments, a plurality of semiconductor devices including the first semiconductor device 210A and the second semiconductor device 210B may each include one or more photodiodes and one or more laser diodes.

For example, when the number of semiconductor devices is four, at least four photodiodes and at least four laser diodes may be provided. In some example embodiments, the number of photodiodes and lasers included in the first optical bridge chip 130 may be equal to or greater than the sum of the numbers of semiconductor devices. The number of photodiodes and the number of laser diodes may change depending on the number of channels allocated to each of a plurality of semiconductor devices.

The semiconductor package 1 according to some example embodiments may perform signal transmission between the plurality of semiconductor devices through the first optical bridge chip 130. As a result, a reduction in delay time, an increase in data transmission speed, maintenance of signal integrity of a plurality of semiconductor devices may be achieved, and relatively high bandwidths of the plurality of semiconductor devices may be obtained, and thus, the performance of the semiconductor package 1 may be improved. In some example embodiments because an optical bridge chip may be relatively miniaturized, the production yield of the optical bridge chip may be improved, and thus, the productivity of the semiconductor package 1 may be improved.

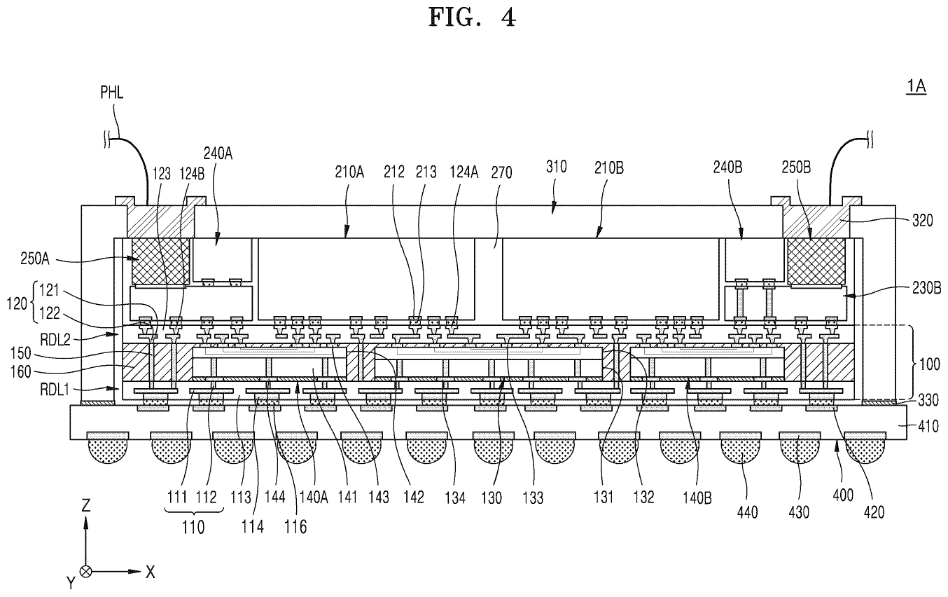

FIG. 4 is a cross-sectional view of a semiconductor package 1A according to some example embodiments. The semiconductor package 1A may be same as or similar in some respects to the semiconductor package 1 of FIGS. 1-3, and therefore may be best understood with reference thereto where like numerals indicate like elements not described again in detail.

Referring to FIG. 4, the semiconductor package 1A may further include a case structure 310 and a package substrate 410 in addition to components of the semiconductor package 1 of FIG. 1 to FIG. 3. The package substrate 410 may have a plurality of first substrate pads 420 formed on an upper surface thereof, and the plurality of first substrate pads 420 may be connected to corresponding lower connection terminals 116 of a plurality of lower connection terminals 116 on a lower surface of the interposer 100. A plurality of second substrate pads 430 may be provided (or arranged) on the lower surface of the package substrate 410, and a plurality of substrate connection terminals 440 may be respectively provided on the plurality of second substrate pads 430.

In some example embodiments, the package substrate 410 may be a printed circuit board. The package substrate 410 may include a base layer, and the base layer may be formed of a plurality of stacked sub-base layers. An upper surface and a lower surface of the base layer may be covered by a solder resist layer. In some example embodiments, the plurality of first substrate pads 420 and the plurality of second substrate pads 430 may not be covered by the solder resist layer and may be exposed from the upper and lower surfaces of the package substrate 410.

In some example embodiments, the base layer may include phenol resin, epoxy resin, and/or polyimide. For example, the base layer may include flame retardant 4 (FR 4 ), tetrafunctional epoxy, polyphenylene ether, epoxy/polyphenylene oxide, bismaleimide triazine (BT), thermount, cyanate ester, polyimide, and/or liquid crystal polymer.

The case structure 310 may surround and cover the components described with reference to FIG. 1 to FIG. 3, such as the interposer 100, the first semiconductor device 210A, and the second semiconductor device 210B. Upper surfaces of the first semiconductor device 210A, the second semiconductor device 210B, the first electronic integrated circuit chip 240A, and the second electronic integrated circuit chip 240B may be coplanar. The upper surfaces of the first semiconductor device 210A, the second semiconductor device 210B, the first electronic integrated circuit chip 240A, and the second electronic integrated circuit chip 240B may be in contact with one surface of the case structure 310. Both ends of the case structure 310 may be attached to an upper surface of the package substrate 410 by adhesive portions 330. The case structure 310 may protect the components therein from physical impact and may also dissipate heat.

The semiconductor package 1A may include a second encapsulant 270. The second encapsulant 270 may be provided on the interposer 100 and may surround the first semiconductor device 210A, the second semiconductor device 210B, the first optical integrated circuit chip 230A, the second optical integrated circuit chip 230B, the first electronic integrated circuit chip 240A, the first fiber array unit 250A, the second electronic integrated circuit chip 240B, and/or the second fiber array unit 250B. For example, the second encapsulant 270 may be or include epoxy molding compound (EMC) or a polymer material and may further include a filler.

An optical communication terminal 320 may be provided (or arranged) on the case structure 310. An external optical fiber PHL may be connected to the first fiber array unit 250A through the optical communication terminal 320. For example, the external optical fiber PHL may be connected to an upper portion of the first fiber array unit 250A through the optical communication terminal 320. In some example embodiments, the external optical fiber PHL may be connected to a side surface of the first fiber array unit 250A.

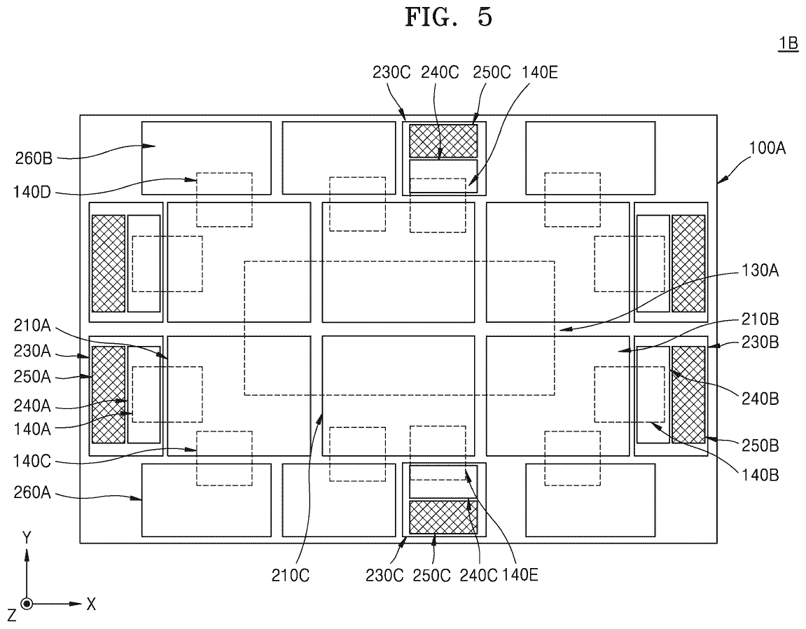

FIG. 5 is a plan view of a semiconductor package 1B according to some example embodiments. The semiconductor package 1B may be same as or similar in some respects to the semiconductor package 1 of FIGS. 1-3 and/or the semiconductor package 1A of FIG. 4, and therefore may be best understood with reference thereto where like numerals indicate like elements not described again in detail.

Referring to FIG. 5, the semiconductor package 1B may include an interposer 100A and include a first semiconductor device 210A, a second semiconductor device 210B, a third semiconductor device 210C, a first memory device 260A, a second memory device 260B, a first optical integrated circuit chip 230A, a second optical integrated circuit chip 230B, a first electronic integrated circuit chip 240A, a first fiber array unit 250A, a second electronic integrated circuit chip 240B, a second fiber array unit 250B, a third optical integrated circuit chip 230C, a third electronic integrated circuit chip 240C, and/or a third fiber array unit 250C provided (or arranged) on the interposer 100A.

The interposer 100A may include a first bridge chip 140A, a second bridge chip 140B, a third bridge chip 140C, a fourth bridge chip 140D, and/or a second optical bridge chip 130A between a first redistribution structure RDL1 and a second redistribution structure RDL2.

A plurality of semiconductor chips, for example, six semiconductor chips including the first semiconductor device 210A, the second semiconductor device 210B, and the third semiconductor device 210C may be provided (or arranged) on the interposer 100A as illustrated in FIG. 5. Part of each of the plurality of semiconductor chips may overlap part of the second optical bridge chip 130A in a planar view.

In order to transmit optical signals between the third semiconductor device 210C and an external device, the third optical integrated circuit chip 230C, the third electronic integrated circuit chip 240C, and the third fiber array unit 250C may be arranged adjacent to the third semiconductor device 210C. The third optical integrated circuit chip 230C, the third electronic integrated circuit chip 240C, and the third fiber array unit 250C may be same as or similar in some respects to the optical integrated circuit chips 230A, 230B, the electronic integrated circuit chips 240A, 240B, and the fiber array units 250A, 250B discussed above with reference to FIGS. 1-4, and may be best understood with reference thereto.

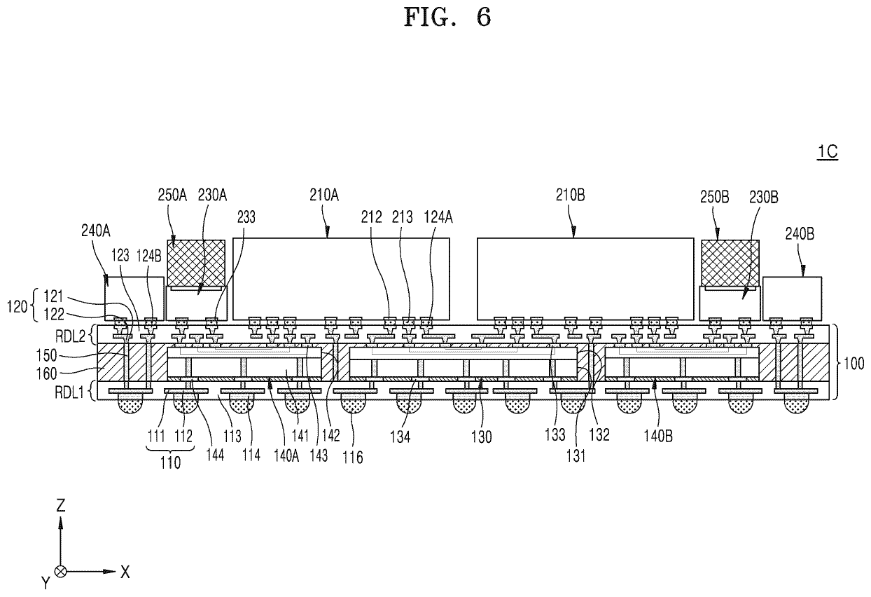

FIG. 6 is a cross-sectional view of a semiconductor package 1C. The semiconductor package 1C may be same as or similar in some respects to the semiconductor package 1 of FIGS. 1-3, the semiconductor package 1A of FIG. 4, and/or the semiconductor package 1B of FIG. 5, and therefore may be best understood with reference thereto where like numerals indicate like elements not described again in detail.

Referring to FIG. 6, a first electronic integrated circuit chip 240A may be provided (or arranged) on an interposer 100 and may be laterally spaced from a first optical integrated circuit chip 230A. The first electronic integrated circuit chip 240A may be between the first optical integrated circuit chip 230A and an outer edge (e.g., horizontal edge) of the interposer 100. A first fiber array unit 250A may be on the first optical integrated circuit chip 230A.

In some example embodiments, the first electronic integrated circuit chip 240A may be between the first optical integrated circuit chip 230A and an outer edge of the interposer 100. In some example embodiments, the first optical integrated circuit chip 230A may be relatively closer to a first semiconductor device 210A than the first electronic integrated circuit chip 240A.

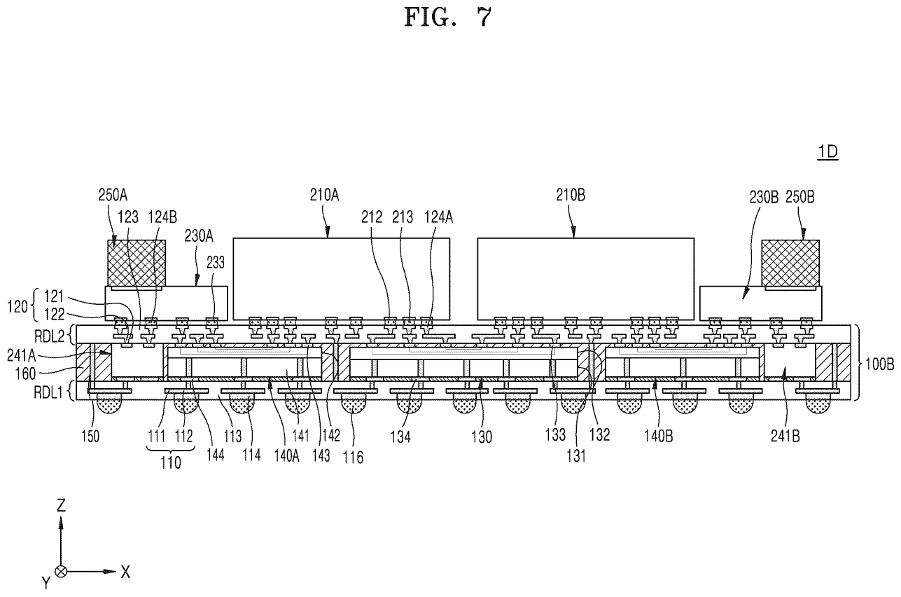

FIG. 7 is a cross-sectional view of a semiconductor package 1D. The semiconductor package 1D may be same as or similar in some respects to the semiconductor package 1 of FIGS. 1-3, the semiconductor package 1A of FIG. 4, the semiconductor package 1B of FIG. 5, and/or the semiconductor package 1C, and therefore may be best understood with reference thereto where like numerals indicate like elements not described again in detail.

Referring to FIG. 7, an interposer 100B may include a first electronic integrated circuit chip 241A. As illustrated,, the semiconductor package 1D of FIG. 7 may include the first electronic integrated circuit chip 241A inside the interposer 100B and below the first fiber array unit 250A and the first optical integrated circuit chip 230A. The semiconductor package 1D of FIG. 7 may also include a second electronic integrated circuit chip 241B inside the interposer 100B and below the second fiber array unit 250B and the second optical integrated circuit chip 230B.

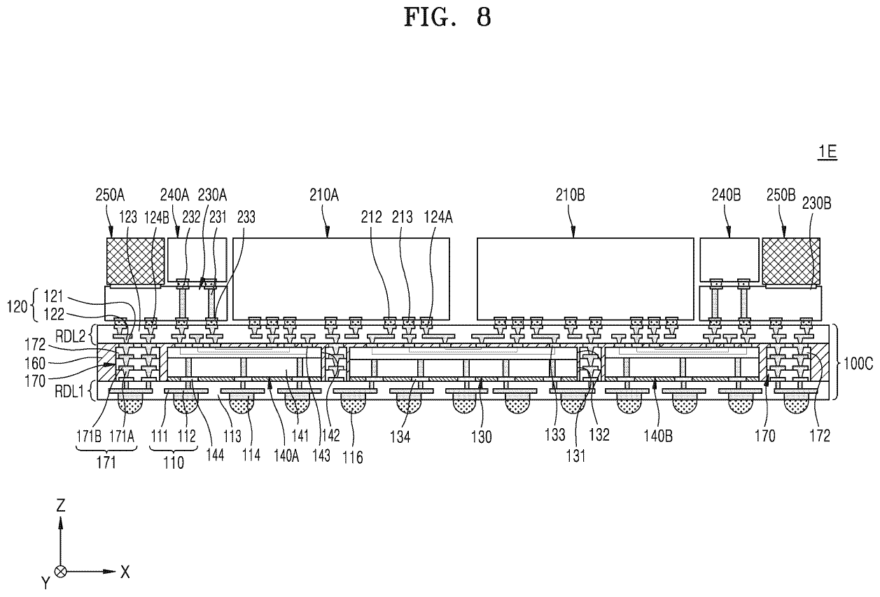

FIG. 8 is a cross-sectional view of a semiconductor package 1E. The semiconductor package 1D may be same as or similar in some respects to the semiconductor package 1 of FIGS. 1-3, the semiconductor package 1A of FIG. 4, the semiconductor package 1B of FIG. 5, the semiconductor package 1C, and/or the semiconductor package 1D, and therefore may be best understood with reference thereto where like numerals indicate like elements not described again in detail.

Referring to FIG. 8, an interposer 100C may further include a core substrate 170 including a plurality of core insulating layers 172 and a plurality of core wires 171. The core substrate 170 may have a cavity, and the cavity may be between two core insulating layers 172. For example, a first optical bridge chip 130, a first bridge chip 140A, and a second bridge chip 140B may be arranged in the cavity.

The core substrate 170 may be provided in a region between the first bridge chip 140A and an outer edge of the interposer 100, a region between the first bridge chip 140A and the first optical bridge chip 130, a region between the second bridge chip 140B and the first optical bridge chip 130, a region between the second bridge chip 140B and the outer edge of the interposer 100, a periphery of the first bridge chip 140A, a periphery of the second bridge chip 140B, and/or a periphery of the first optical bridge chip 130.

The plurality of conductive posts 150 disclosed with reference to FIG. 1 to FIG. 7 may be replaced with the plurality of core wires 171 provided inside the core substrate 170. The plurality of core wires 171 may include core line wiring 171B and core via wiring 171A. The core substrate 170 may be provided (or arranged) on a first redistribution structure RDL1. A first encapsulant 160 may surround the core substrate 170.

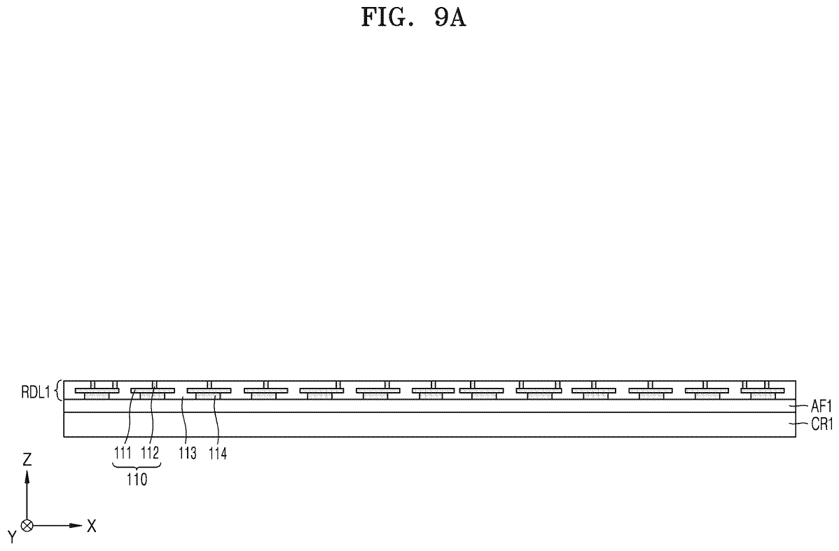

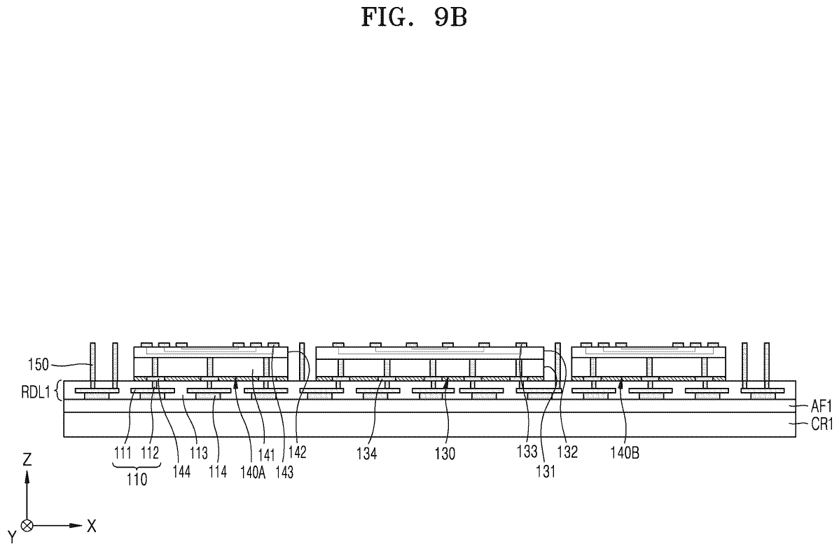

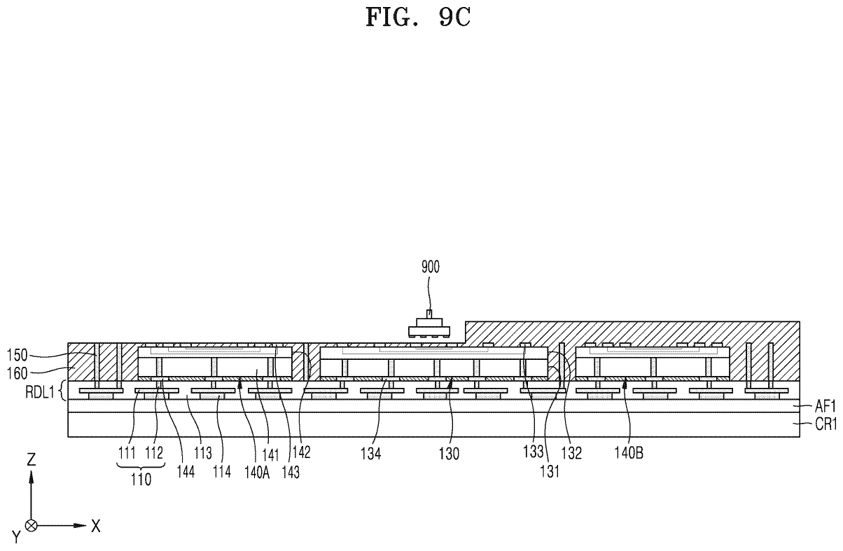

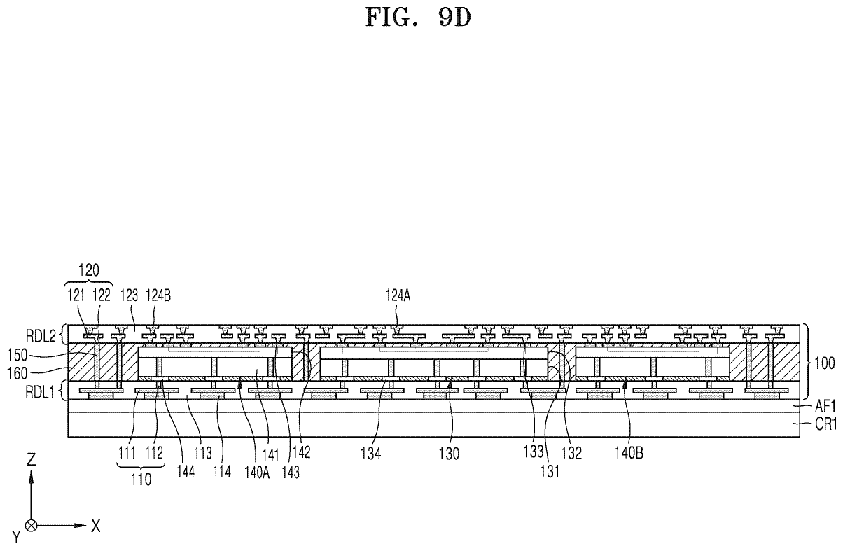

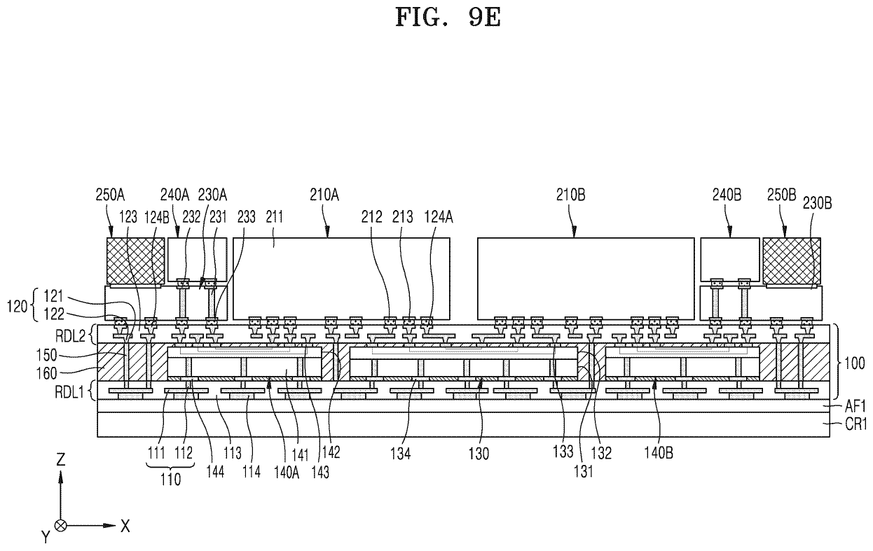

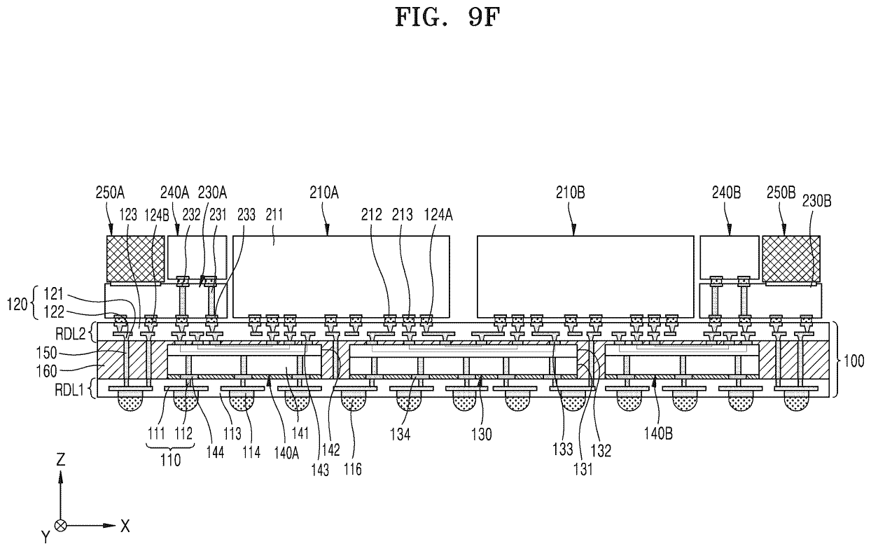

FIGS. 9A, 9B, 9C, 9D, 9E, and FIG. 9F are cross-sectional views illustrating a method of manufacturing the semiconductor package 1, according to some example embodiments. The components discussed in the manufacturing method may be best understood with reference to the above example embodiments.

Referring to FIG. 9A, a first redistribution structure RDL1 may be formed on a carrier CR1. The first redistribution structure RDL1 may be fixed and adhered to the carrier CR1 through an adhesive layer AF1. In the first redistribution structure RDL1, a first redistribution insulating layer 113 and a first redistribution pattern 110 may be alternately formed through the redistribution process described above.

Referring to FIG. 9B, after a plurality of conductive posts 150 are formed on the first redistribution structure RDL1, a first optical bridge chip 130, a first bridge chip 140A, and a second bridge chip 140B may be arranged.

Referring to FIG. 9C, after a first encapsulant 160 is formed on the first redistribution structure RDL1, a mechanical and chemical polishing process may be performed, for example, using a polishing tool 900. After the first encapsulant 160 is formed, a plurality of first upper chip pads 133 and a plurality of first upper chip pads 143 may be exposed from the first encapsulant 160 through, for example, a polishing process.

Referring to FIG. 9D, a second redistribution structure RDL2 may be formed on the first encapsulant 160. The second redistribution structure RDL2 may be formed through a redistribution process.

Referring to FIG. 9E, a first semiconductor device 210A, a second semiconductor device 210B, a first optical integrated circuit chip 230A, a second optical integrated circuit chip 230B, a first electronic integrated circuit chip 240A, a first fiber array unit 250A, a second electronic integrated circuit chip 240B, and a second fiber array unit 250B may be arranged on the second redistribution structure RDL2.

The first semiconductor device 210A, the second semiconductor device 210B, the first optical integrated circuit chip 230A, and the second optical integrated circuit chip 230B may be arranged on the second redistribution structure RDL2, and the first electronic integrated circuit chip 240A and the first fiber array unit 250A may be provided (or arranged) on the first optical integrated circuit chip 230A, and the second electronic integrated circuit chip 240B and the second fiber array unit 250B may be provided (or arranged) on the second optical integrated circuit chip 230B.

Referring to FIG. 9F, the carrier CR1 and the adhesive layer AF1 may be removed from the first redistribution structure RDL1, and a plurality of lower connection terminals 116 may be respectively formed on a plurality of lower connection pads 114 that are provided (or arranged) on a lower surface of the first redistribution structure RDL1.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A semiconductor package comprising:
an interposer including a first redistribution structure, a second redistribution structure, a first optical bridge chip between the first redistribution structure and the second redistribution structure, and a first bridge chip between the first redistribution structure and the second redistribution structure and laterally separated from the first optical bridge chip;
a plurality of semiconductor devices including a first semiconductor device and a second semiconductor device, the first semiconductor device being on the interposer, and the second semiconductor device being on the interposer and laterally separated from the first semiconductor device; and
a first optical integrated circuit chip on the interposer and laterally separated from the first semiconductor device,
wherein a first region of the first optical bridge chip vertically overlaps a first region of the first semiconductor device, and
a first part of a second region of the first optical bridge chip vertically overlaps a first region of the second semiconductor device.

2. The semiconductor package of claim 1, wherein
a first region of the first bridge chip vertically overlaps a second region of the first semiconductor device, and
a first part of a second region of the first bridge chip vertically overlaps a first region of the first optical integrated circuit chip.

3. The semiconductor package of claim 1, wherein
the first optical integrated circuit chip does not vertically overlap the first optical bridge chip, and
one of side surfaces of the first optical integrated circuit chip faces one of side surfaces of each of the plurality of semiconductor devices.

4. The semiconductor package of claim 1, wherein
the interposer further includes a conductive post, and
the conductive post is in at least one of a region between the first bridge chip and the first optical bridge chip and a region between the first bridge chip and an outer edge of the interposer.

5. The semiconductor package of claim 1, wherein
the first optical bridge chip includes a through-electrode passing through at least part of the first optical bridge chip, and
the through-electrode is electrically connected to the first redistribution structure.

6. The semiconductor package of claim 1, further comprising:
a first electronic integrated circuit chip electrically connected to the first optical integrated circuit chip; and
a first fiber array unit on the first optical integrated circuit chip,
wherein the first fiber array unit includes a plurality of optical fibers connected to the first optical integrated circuit chip.

7. The semiconductor package of claim 1, wherein the first optical bridge chip and the first optical integrated circuit chip respectively include a first bridge optical waveguide and a first optical waveguide.

8. The semiconductor package of claim 1, wherein
the first optical bridge chip includes a plurality of laser diodes and a plurality of photodiodes,
a number of the laser diodes is equal to or greater than a number of the plurality of semiconductor devices, and
a number of the photodiodes is equal to or greater than the number of the plurality of semiconductor devices.

9. The semiconductor package of claim 1, wherein
the first optical bridge chip includes:
a plurality of interfaces electrically connected to the plurality of semiconductor devices;
and a plurality of optical channels for communication between the plurality of interfaces, and
the first optical bridge chip is configured to directly communicate with the plurality of interfaces in a single hop (1-hop).

10. The semiconductor package of claim 1, further comprising:
a second optical integrated circuit chip on the interposer and laterally separated from the second semiconductor device,
wherein the interposer comprises a second bridge chip between the first redistribution structure and the second redistribution structure and laterally separated from the first optical bridge chip, and
a first region of the second bridge chip vertically overlaps the second semiconductor device, and a first part of a second region of the second bridge chip vertically overlaps at least part of the second optical integrated circuit chip.

11. The semiconductor package of claim 1, further comprising:
a first memory device on the interposer and laterally separated from the plurality of semiconductor devices,
wherein the interposer includes a third bridge chip between the first redistribution structure and the second redistribution structure and laterally separated from the first optical bridge chip,
the first memory device includes a plurality of stacked memory chips, and
a first region of the third bridge chip vertically overlaps the first memory device, and a first part of a second region of the third bridge chip vertically overlaps one of the plurality of semiconductor devices.

12. The semiconductor package of claim 1, wherein
the interposer includes a core substrate between the first redistribution structure and the second redistribution structure,
the core substrate includes a core insulating layer and a core wire, and
the core substrate includes a plurality of cavities, and the first optical bridge chip and the first bridge chip are in the plurality of cavities.

13. The semiconductor package of claim 6, wherein
the first electronic integrated circuit chip is laterally separated from the first optical integrated circuit chip,
the first electronic integrated circuit chip is electrically connected to the first optical integrated circuit chip through the second redistribution structure, and
the first fiber array unit is on an upper surface of the first optical integrated circuit chip.

14. The semiconductor package of claim 6, wherein
the first electronic integrated circuit chip is on the second redistribution structure and is electrically connected to the first optical integrated circuit chip through the second redistribution structure, and
the first fiber array unit is on an upper surface of the first optical integrated circuit chip.

15. A semiconductor package comprising:
an interposer including a first redistribution structure, a second redistribution structure, a first optical bridge chip between the first redistribution structure and the second redistribution structure, and a first bridge chip and a third bridge chip, the first bridge chip and the third bridge chip being between the first redistribution structure and the second redistribution structure and laterally separated from the first optical bridge chip;
a plurality of semiconductor devices including a first semiconductor device and a second semiconductor device, the first and second semiconductor devices being on the interposer;
a first optical integrated circuit chip on the interposer and laterally separated from the first semiconductor device;
a first electronic integrated circuit chip electrically connected to the first optical integrated circuit chip;
a first fiber array unit on the first optical integrated circuit chip; and
a first memory device on the interposer and laterally separated from the first semiconductor device,
wherein the interposer includes a conductive post between the first redistribution structure and the second redistribution structure and in at least one of a region between the first bridge chip and the first optical bridge chip and a region between the first bridge chip and an outer edge of the interposer,
the first fiber array unit includes a plurality of optical fibers connected to the first optical integrated circuit chip,
the first optical bridge chip and the first optical integrated circuit chip respectively include a first bridge optical waveguide and a first optical waveguide, and
the first semiconductor device includes a logic chip, and the first memory device includes a plurality of stacked memory chips.

16. The semiconductor package of claim 15, wherein
a first region of the first optical bridge chip vertically overlaps a first region of the first semiconductor device, and
a first part of a second region of the first optical bridge chip vertically overlaps a first region of the second semiconductor device,
a first region of the first bridge chip vertically overlaps a second region of the first semiconductor device, and a first part of a second region of the first bridge chip vertically overlaps at least part of the first optical integrated circuit chip,
the first optical integrated circuit chip does not vertically overlap the first optical bridge chip, and one of side surfaces of the first optical integrated circuit chip faces one of side surfaces of each of the plurality of semiconductor devices, and
a first region of the third bridge chip vertically overlaps the first memory device, and a first part of a second region of the third bridge chip vertically overlaps one of the plurality of semiconductor devices.

17. The semiconductor package of claim 15, wherein
the first optical bridge chip includes a plurality of laser diodes and a plurality of photodiodes,
a number of the laser diodes is equal to or greater than a number of the plurality of semiconductor devices,
a number of the photodiodes is equal to or greater than the number of the plurality of semiconductor devices,
the first optical bridge chip includes,
a plurality of interfaces electrically connected to the plurality of semiconductor devices; and
a plurality of optical channels for communication between the plurality of interfaces, and
the first optical bridge chip is configured to directly communicate with the plurality of interfaces in a single hop (1-hop).

18. The semiconductor package of claim 15, wherein
the first optical integrated circuit chip includes a through-electrode,
the first electronic integrated circuit chip is on an upper surface of the first optical integrated circuit chip, and the first fiber array unit is on the upper surface of the first optical integrated circuit chip and laterally separated from the first electronic integrated circuit chip,
the through-electrode is electrically connected to the first electronic integrated circuit chip and the second redistribution structure, and
the first fiber array unit is farther from the first semiconductor device than the first electronic integrated circuit chip.

19. The semiconductor package of claim 15, further comprising:
a plurality of first semiconductor devices, wherein
signals are transmitted between the plurality of first semiconductor devices through the first optical bridge chip and are transmitted between the first semiconductor device of the plurality of first semiconductor devices and the first optical integrated circuit chip through the first bridge chip, and
signals are transmitted between the first memory device and the plurality of first semiconductor devices through the third bridge chip.

20. A semiconductor package comprising:
an interposer including a first redistribution structure, a second redistribution structure, a first optical bridge chip between the first redistribution structure and the second redistribution structure, a first bridge chip between the first redistribution structure and the second redistribution structure and laterally separated from the first optical bridge chip, and a plurality of conductive posts;
a plurality of semiconductor devices including a first semiconductor device and a second semiconductor device, the first semiconductor device being on the interposer, and the second semiconductor device being on the interposer and laterally separated from the first semiconductor device;
a first optical integrated circuit chip on the interposer and laterally separated from the first semiconductor device;
a first electronic integrated circuit chip electrically connected to the first optical integrated circuit chip; and
a first fiber array unit on the first optical integrated circuit chip,
wherein a first region of the first optical bridge chip vertically overlaps a first region of the first semiconductor device, and a first part of a second region of the first optical bridge chip vertically overlaps a first region of the second semiconductor device,
a first region of the first bridge chip vertically overlaps a second region of the first semiconductor device, and a first part of a second region of the first bridge chip vertically overlaps a first region of the first optical integrated circuit chip,
the first optical integrated circuit chip does not vertically overlap the first optical bridge chip,
at least one conductive post of the plurality of conductive posts is in at least one of a region between the first bridge chip and the first optical bridge chip and a region between the first bridge chip and an outer edge of the interposer,
the first optical bridge chip includes a through-electrode passing through at least part of the first optical bridge chip and electrically connected to the first redistribution structure,
the first optical bridge chip and the first optical integrated circuit chip respectively include a first bridge optical waveguide and a first optical waveguide,
the first fiber array unit includes a plurality of optical fibers connected to the first optical integrated circuit chip,
the first optical bridge chip includes a plurality of laser diodes and a plurality of photodiodes,
a number of the laser diodes is equal to or greater than a number of the plurality of semiconductor devices,
a number of the photodiodes is equal to or greater than the number of the plurality of semiconductor devices,
the first optical bridge chip includes,
a plurality of interfaces electrically connected to the plurality of semiconductor devices; and
a plurality of optical channels for communication between the plurality of interfaces, and
the first optical bridge chip is configured to directly communicate with the plurality of interfaces in a single hop.
